(19) United States
(12) Patent Application Publication
(10) Pub. No.: US 2024/0042952 A1
(43) Pub. Date: Feb. 8, 2024

(54) POWER CONVERSION APPARATUS, CONNECTOR-FIXING STRUCTURE AND POWER-CONVERSION-APPARATUS PRODUCTION METHOD

(71) Applicant: FUJI ELECTRIC CO., LTD., Kawasaki-shi (JP)

(72) Inventor: Shun FUKUCHI, Suzuka-shi (JP)

(21) Appl. No.: 18/473,709

(22) Filed: Sep. 25, 2023

Related U.S. Application Data
(63) Continuation of application No. PCT/JP2022/038015, filed on Oct. 12, 2022.

(30) Foreign Application Priority Data
Oct. 12, 2021 (JP) 2021-167349

(51) Int. Cl. B60R 16/023; B60L 53/302; H05K 7/20

(52) U.S. Cl. CPC B60R 16/0238; B60L 53/302; H05K 7/20909; H05K 7/20172

(57) ABSTRACT

A power conversion apparatus includes a board including a device for power conversion mounted on the board; a connector fixed to the board and configured to electrically connect the board to an external side; a top plate formed of a metal plate and arranged to cover the board; and a bottom plate formed of a metal plate and arranged to face the top plate. The bottom plate includes a bottom-plate folded part that is arranged on an end part of the bottom plate on which the connector is arranged, and is folded to contact the connector whereby preventing movement of the connector.

### CROSS-REFERENCE TO RELATED APPLICATION

This application is a continuation of PCT application No. PCT/JP2022/038015, filed on Oct. 12, 2022, which claims priority of Japanese Patent Application No. 2021-167349 filed on Oct. 12, 2021, disclosure of which is incorporated herein.

### BACKGROUND OF THE INVENTION

### Field of the Invention

The present invention relates to a power conversion apparatus, a connector-fixing structure and a power-conversion-apparatus production method.

### Description of the Background Art

Conventionally, an apparatus including a connector (terminal) electrically connected to an external side and its board is known. Such an apparatus is disclosed in Japanese Unexamined Patent Publications No. JP 2012-139012 and No. JP 2019-80005.

The above Japanese Unexamined Patent Publication No. JP 2012-139012 discloses a power conversion apparatus including a power semiconductor module configured to convert DC power from a battery into AC power. This power conversion apparatus is supplied with DC power from the battery through a DC terminal and provides the converted AC power through an AC terminal. In the power conversion apparatus disclosed in the above Japanese Unexamined Patent Publication No. JP 2012-139012, the DC and AC terminals are supported by a supporting member. The supporting member is fixed to a case that houses the power semiconductor module so that the DC and AC terminals are fixed to limit their movements.

The above Japanese Unexamined Patent Publication No. JP 2019-80005 discloses an electronic circuit unit including a board, on which a plurality of connectors is mounted, and a housing housing the board. The plurality of connectors is fixed to the board by screws, bolts, etc., for example. The board is fixed inside the housing by resin potting. In the electronic circuit unit disclosed in the above Japanese Unexamined Patent Publication No. 2019-80005, the plurality of connectors is fixed to the housing by being press-fitted into engagement grooves formed in the housing to limit their movements.

If a load (force) is applied to a connector (terminal) for electrical connection between an external side and a board, movement of the connector may cause a defect such as a crack of solder that electrically connects the connector to the board, or a fault such as board warpage. To address this, the connectors in the above Japanese Unexamined Patent Publications Nos. JP 2012-139012 and 2019-80005 are fixed to limit their movements. However, in the power conversion apparatus described in the above Japanese Unexamined Patent Publication No. JP 2012-139012, because the supporting member, which supports the connectors (DC and AC terminals), is fixed to the housing, the housing and the support member necessarily have screw holes into which screws are inserted to fix the support member to the housing. For this reason, it is necessary to provide a configuration for fixing connectors such as screw holes to the support member and the housing and to fix the support member to the housing by screwing, and as a result the apparatus configuration is complicated. In addition, although not stated in the above Japanese Unexamined Patent Publication No. JP 2012-139012, in a case in which fasteners such as screws are used to fix the connectors to the housing in production of the apparatus, working time for production works will be increased by a burden of fastening the fasteners.

In a case in which the connectors fixed to the board are fixed by being press-fitted into the engagement grooves formed in the housing as stated in the electronic circuit unit disclosed in the above Japanese Unexamined Patent Publication No. 2019-80005, the engagement grooves are necessarily accurately formed by accurate processing to prevent movement of the connectors. Although not stated in the above Japanese Unexamined Patent Publication No. 2019-80005, in a case in which the housing is formed by cutting aluminum material, processing time for cutting is increased to accurately form the housing, and as a result working time for producing the apparatus is correspondingly increased.

### SUMMARY OF THE INVENTION

The present invention is intended to solve the above problems, and one object of the present invention is to provide a power conversion apparatus, a connector-fixing structure and a power-conversion-apparatus production method capable of preventing apparatus configuration from becoming complicated while preventing increase of work time for production work.

In order to attain the aforementioned object, a power conversion apparatus according to a first aspect of the present invention includes a board including a device for power conversion mounted on the board; a connector fixed to the board and configured to electrically connect the board to an external side; a top plate formed of a metal plate and arranged to cover the board; and a bottom plate formed of a metal plate and arranged to face the top plate, wherein the bottom plate formed of a metal plate includes a bottom-plate folded part that is arranged on an end part of the bottom plate on which the connector is arranged, and is folded to contact the connector whereby preventing movement of the connector.

In the power conversion apparatus according to the first aspect of the present invention, as discussed above, the bottom plate formed of a metal plate includes a bottom-plate folded part that is arranged on an end part of the bottom plate on which the connector is arranged, and is folded to contact the connector whereby preventing movement of the connector. Accordingly, the connector can be fixed to the board while preventing movement of the connector by means of the bottom-plate folded part, which is formed by folding the bottom plate formed of a metal plate, without using fasteners such as screws. Because metal plate folding (presswork) can accurately convert material from one form into another form (accurate processing) while reducing processing time as compared with cutting, it is possible to prevent time increase of processing that forms a structure that prevents movement of the connector when the connector is fixed to the board. Consequently, it is possible to prevent apparatus configuration from becoming complicated while preventing increase of work time for production work. In addition, because movement of the connector can be prevented by the bottom-plate folded part, which is formed by folding the bottom plate, increase of the number of parts can be prevented while preventing movement of the connector as compared with a case in which the connector is fixed to a housing by means of fasteners such as screws.

In the power conversion apparatus according to the aforementioned first aspect, it is preferable that the connector has a bottom-plate-side groove into which the bottom-plate folded part is inserted; and that the bottom-plate folded part contacts an interior surface of the bottom-plate-side groove with being inserted into the bottom-plate-side groove of the connector whereby preventing movement of the connector. According to this configuration, movement of the connector can be effectively prevented by inserting the bottom-plate folded part into the groove of the connector. Consequently, defects such as solder cracking or faults such as board warpage caused by the movement of the connector can be effectively prevented.

In this configuration, it is preferable that the bottom-plate folded part has a convex section that bulges in an area inserted into the bottom-plate-side groove of the connector in a thickness direction of the bottom-plate folded part to prevent movement of the connector. According to this configuration in which the convex section is provided, a length of the bottom-plate folded part of the bottom plate in the thickness direction can be increased, and as a result movement of the connector can be more effectively prevented by contact of the convex section of the bottom-plate folded part with the connector. Because the movement of the connector can be more effectively prevented, defects such as solder cracking or faults such as board warpage caused by the movement of the connector can be more effectively prevented.

In the power conversion apparatus in which the bottom-plate folded part has the convex section, it is preferable that the top plate has a top-plate folded part that is folded on an end part of the top plate on which the connector is arranged; the connector has a top-plate-side groove into which the top-plate folded part is inserted; and the top-plate folded part has a flat surface, and contacts an interior surface of the top-plate-side groove with being inserted into the top-plate-side groove whereby preventing movement of the connector. According to this configuration, in addition to prevention of movement of the connector by the convex section of the bottom-plate folded part, the movement of the connector can be more effectively prevented by the top-plate folded part. Because the movement of the connector can be further more effectively prevented if a load is applied to the connector, defects such as solder cracking or faults such as board warpage caused by the movement of the connector can be further more effectively prevented.

In the power conversion apparatus according to the aforementioned first aspect, it is preferable that a frame to which the board is attached is further provided, wherein the top plate is arranged to cover the board attached to the frame; and the bottom plate is arranged to cover the frame with facing the top plate. According to this configuration, even in a case in which a frame that holds the board is produced by removing its material by cutting, etc., movement of the connector can be prevented not by the frame but by the bottom plate, by folding the bottom plate formed of a metal plate. Accordingly, even in a case in which a frame that holds the board is produced by removing its material by cutting, etc., movement of the connector can be prevented by the bottom plate arranged to cover the frame while preventing increase of work time for production work.

In the power conversion apparatus according to the aforementioned first aspect, it is preferable that a cooling fan configured to blow cooling air to cool the device mounted on the board is further provided, wherein the bottom plate has a ventilation hole formed to flow the cooling air from the cooling fan to the outside. According to this configuration, in a case in which the bottom-plate folded part configured to prevent movement of the connector is provided by folding the bottom plate, the ventilation hole can prevent the folded part of the bottom plate from blocking a flow path of cooling air. Consequently, in a case in which bottom plate is folded to prevent movement of the connector, reduction of cooling efficiency of the cooling fan can be prevented.

In this configuration, it is preferable that the bottom-plate folded part is formed by folding the bottom plate in a stepped shape on the end part of the bottom plate on which the connector is arranged; and the ventilation hole is formed in a stepped section of the bottom plate formed by folding the bottom plate in a stepped shape. According to this configuration in which the ventilation hole is formed in a stepped section of the bottom plate formed by folding the bottom plate in a stepped shape, the ventilation hole can have a larger opening area. As a result, it is possible to further prevent the folded part of the bottom plate from blocking a flow path of cooling air. Consequently, it is possible to further prevent reduction of cooling efficiency of the cooling fan.

In the power conversion apparatus according to the aforementioned first aspect, it is preferable that the connector includes a connector protrusion protruding toward the bottom plate; and the bottom-plate folded part has a concave cutout that is formed to contact the connector protrusion whereby preventing movement of the connector in a direction orthogonal to the thickness direction of the bottom-plate folded part and a direction in which the top plate and the bottom plate face each other. According to this configuration, the connector protrusion and the cutout of the bottom-plate folded part can prevent movement of the connector in a direction orthogonal to the thickness direction of the bottom-plate folded part and a direction in which the top plate and the bottom plate face each other. Consequently, because the movement of the connector can be further prevented by contact of the cutout and the connector protrusion, defects such as solder cracking or faults such as board warpage caused by the movement of the connector can be further prevented.

In the power conversion apparatus according to the aforementioned first aspect, it is preferable that a first connector configured to supply the board with DC power from an external battery installed on a vehicle and a second connector configured to supply an external load with AC power converted by power conversion function of the device mounted on the board, are provided as the connector; and the bottom-plate folded part contacts the first and second connectors whereby preventing movement of the first and second connectors. According to this configuration, even when vibration caused by vehicle motion is applied to the power conversion apparatus, the bottom-plate folded part can effectively prevent movement of the first connector and the second connector.

A connector-fixing structure according to a second aspect of the present invention includes a board including an electronic part mounted on the board; a connector fixed to the board and configured to electrically connect the board to an external side; a top plate formed of a metal plate and arranged to cover the board; and a bottom plate formed of a metal plate and arranged to face the top plate, wherein the bottom plate formed of a metal plate includes a bottom-plate folded part that is arranged on an end part of the bottom plate on which the connector is arranged, and is folded to contact the connector whereby preventing movement of the connector.

In the connector fixing structure according to the second aspect of the present invention, as discussed above, the bottom plate formed of a metal plate includes a bottom-plate folded part that is arranged on an end part of the bottom plate on which the connector is arranged, and is folded to contact the connector whereby preventing movement of the connector. Accordingly, the connector can be fixed to the board while preventing movement of the connector by means of the bottom-plate folded part, which is formed by folding the bottom plate formed of a metal plate, without using fasteners such as screws. Because metal plate folding (presswork) can accurately convert material from one form into another form (accurate processing) while reducing processing time as compared with cutting, it is possible to prevent time increase of processing that forms a structure that prevents movement of the connector. Consequently, it is possible to provide a connector-fixing structure capable of preventing apparatus configuration from becoming complicated while preventing increase of work time for production work. In addition, because movement of the connector can be prevented by the bottom-plate folded part, which is formed by folding the bottom plate, increase of the number of parts can be prevented while preventing movement of the connector as compared with a case in which the connector is fixed to a housing by means of fasteners such as screws.

A power-conversion-apparatus production method according to a third aspect of the present invention includes a step of fixing a connector configured to electrically connect an external side to a board including a device for power conversion mounted on the board; a step of arranging a top plate formed of a metal plate to cover a top surface side of the board; a step of folding by presswork an end part of a bottom plate, which is formed of a metal plate and arranged on a bottom surface side of the board, on a side where the connector is arranged; and a step of arranging the bottom plate, which is formed of a metal plate, to face the top plate so that a bottom-plate folded part of the bottom plate, which has been folded, contacts the connector whereby preventing movement of the connector.

In the power-conversion-apparatus production method according to the third aspect of the present invention, as discussed above, a step of folding a bottom plate arranged on a bottom surface side of the board an end part of the bottom-plate on which the connector is arranged by pressing; and a step of arranging the bottom plate, which is formed of a metal plate, to face the top plate so that the bottom-plate folded part of the bottom plate, which has been folded, contacts the connector are provided. Accordingly, the connector can be fixed to the board while preventing movement of the connector by means of the bottom-plate folded part, which is formed by folding the bottom plate formed of a metal plate, without using fasteners such as screws. Because metal plate folding (presswork) can accurately convert material from one form into another form (accurate processing) while reducing processing time as compared with cutting, it is possible to prevent time increase of processing that forms a structure that prevents movement of the connector when the connector is fixed to the board. Consequently, it is possible to provide a power-conversion-apparatus production method capable of preventing apparatus configuration from becoming complicated while preventing increase of work time for production work. In addition, because movement of the connector can be prevented by the bottom-plate folded part, which is formed by folding the bottom plate, increase of the number of parts can be prevented while preventing movement of the connector as compared with a case in which the connector is fixed to a housing by means of fasteners such as screws.

### EFFECTS OF INVENTION

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram showing a vehicle with a power conversion apparatus according to one embodiment of the present invention installed thereon;

FIG. 2 is a perspective diagram showing the configuration of the power conversion apparatus according to the embodiment;

FIG. 3 is an exploded perspective diagram showing a board, a frame, a top plate, a bottom plate, and connectors in the power conversion apparatus according to the embodiment;

FIG. 4 is a cross-sectional view taken along a line 4-4 in FIG. 2;

FIG. 5 is a schematic diagram showing cooling fins of the frame;

FIG. 6 is a perspective diagram showing the bottom plate;

FIG. 7 is an enlarged diagram of a part in FIG. 4;

FIG. 8A is a top plan view of the connector from the top plate side for illustrating a structure for fixing the connectors.

FIG. 8B is a bottom plan view of the connector from the bottom plate side for illustrating the structure for fixing the connectors.

FIG. 9 is a cross-sectional view taken along a line 9-9 in FIG. 7;

FIG. 10 is a perspective diagram structures for fixing cooling fans; and

FIG. 11 is a flowchart illustrating a power-conversion-apparatus production method according to the embodiment.

### DESCRIPTION OF THE PREFERRED EMBODIMENTS

Embodiments embodying the present invention are hereinafter described on the basis of the drawings.

### Configuration of Power Conversion Apparatus of the Embodiment

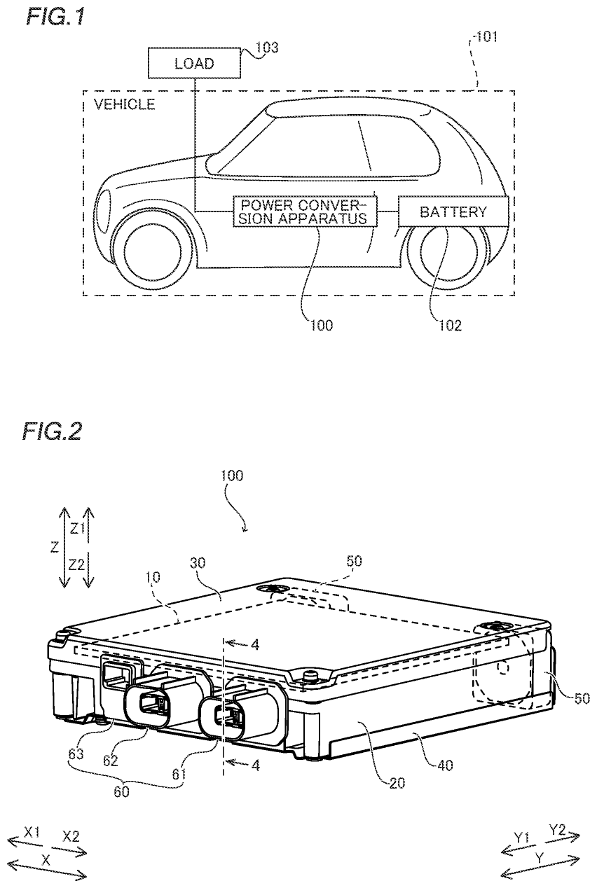

A power conversion apparatus 100 according to one embodiment of the present invention is now described with reference to FIGS. 1 to 10.

As shown in FIG. 1, the power conversion apparatus 100 according to this embodiment is an inverter installed on a vehicle 101. The vehicle 101 is, for example, an electric vehicle including a battery 102. The power conversion apparatus 100 is configured to convert DC (direct current) power supplied from the battery 102 installed on the vehicle 101 into AC (alternating current) power and supply the converted AC power to a load 103. The load 103 is, for example, an electrical appliance that is driven by an AC power supply of 100 V.

As shown in FIG. 2, the power conversion apparatus 100 includes a board 10, a frame 20, a top plate 30, a bottom plate 40, cooling fans 50 and connectors 60.

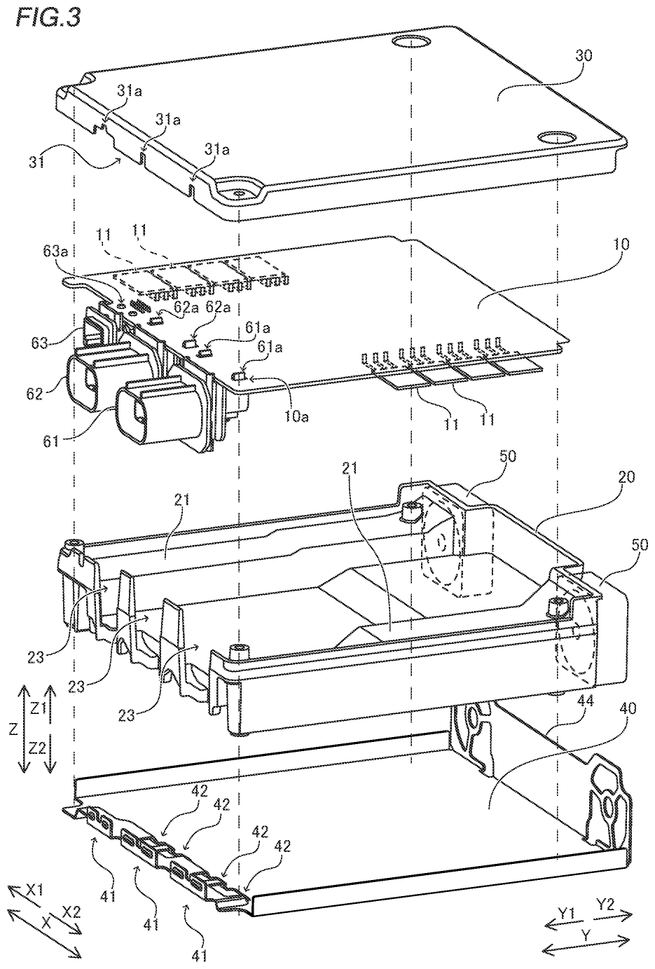

As shown in FIG. 3, devices 11 for power conversion are mounted on the board 10. Specifically, a plurality of devices 11 is electrically connected to the board 10 by soldering. The board 10 is constructed of a printed circuit board. The board 10 is arranged in an X-Y plane in the power conversion apparatus 100. The board 10 is arranged on a Z1-direction side of the power conversion apparatus 100 (top plate 30 side). The devices 11 are examples of “device” and “electronic part” in the claims.

The devices 11 are arranged on a Z2-direction side (bottom side) of the board 10. The device 11 is a semiconductor element (switching element) that includes, for example, an insulated gate bipolar transistor (IGBT) or a metal-oxide-semiconductor field-effect transistor (MOSFET). In the power conversion apparatus 100, the plurality of devices 11 mounted on the board 10 is connected as a full bridge connection to form an inverter circuit that converts DC power into AC power. The devices 11 will generate heat in switching operation.

The board 10 is attached to the frame 20 as shown in FIG. 2. Specifically, the board 10 is attached to the frame 20 by means of fasteners such as screws (not shown). The frame 20 divides interior space of the power conversion apparatus 100 into a Z1-direction side (top side) and a Z2-direction side (bottom side). The board 10 is arranged on the Z1-direction side of the frame 20. The frame 20 forms side parts of the power conversion apparatus 100. The connectors 60 are arranged on the Y1-direction side of the frame 20. The cooling fans 50 are arranged on the Y2-direction side of the frame 20.

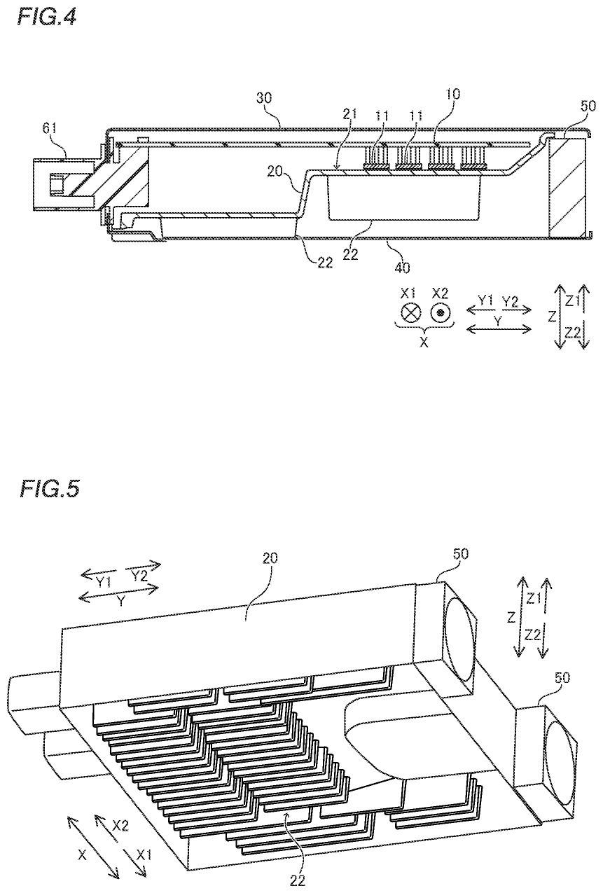

Also, the frame 20 has cooling surfaces 21, as shown in FIGS. 3 and 4. The cooling surfaces 21 are arranged on a side of the frame 20 where the board 10 is arranged (on the Z1-direction side). The cooling surfaces 21 can cool the devices 11. Specifically, the devices 11 are tightly coupled to the cooling surfaces 21 by means of a heat transfer material such as a heat conduction sheet (not shown). Accordingly, the devices 11 can be cooled by exchanging heat with the frame 20 through the cooling surfaces 21.

For example, the plurality of devices 11 can be fixed to the cooling surfaces 21 by an adhesive member with being electrically insulated from the cooling surfaces by means of an insulating plate such as a ceramic plate. In this arrangement, improvement of heat dissipation performance can be expected as compared with a case of a heat dissipation structure in which the plurality of devices 11 is fixed to the cooling surfaces 21 by means of heat dissipation materials such as silicon grease. In other words, the power conversion apparatus 100 includes the board 10 which includes the devices 11 for power conversion mounted on the board, and the frame 20 which holds the board 10 and has the cooling surfaces 21 to which the devices 11 are fixed by means of an adhesive member with an electrically insulating plate (heat transfer member) being interposed between each of the devices 11 and its corresponding cooling surface 21. The devices 11 are fixed to the cooling surfaces 21 with an electrically insulating plate (heat transfer member) such as ceramics, and an adhesive material interposed between each of the devices 11 and its corresponding cooling surface 21.

Also, the frame 20 has cooling fins 22, as shown in FIGS. 4 and 5. The cooling fins 22 are configured to dissipate heat from the devices 11. The cooling fin 22 is a plate-shaped member extending in a Y-Z plane. A number of cooling fins 22 is arranged on the Z2-direction side of the frame 20. The cooling fins 22 are configured to be able to exchange heat with outside air through cooling air from the cooling fans 50. Heat of the frame 20 transferred from the devices 11 can be dissipated by heat exchange between each of the cooling fins 22 and outside air. The frame 20 is produced by cutting a metal such as aluminum alloy (removing its material by cutting), for example. In other words, the cooling surfaces 21 and the cooling fins 22 are integrally formed in the frame 20.

The number of the cooling fins 22 on a downstream side (Y1-direction side) is greater than the number of the cooling fins 22 on an upstream side (Y2-direction side) where cooling fans 50 (described later) are arranged. Because the devices 11 mounted on the board 10 are fixed on the upstream side (Y2-direction side), the cooling fins 22 on the upstream side (Y2-direction side) have a higher height (size in a Z direction). The cooling fins 22 on the downstream side (Y1-direction side) have a lower height (size in the Z direction) (see FIG. 4). In this arrangement, the total surface area of the cooling fins 22 on the downstream side (Y2-direction side) where their height is lower can be increased. For example, in a case in which the devices 11 each having a relatively lower height in the Z direction are arranged on the upstream side (on the Y2-direction side) of the board 10, and magnetic components such as power transformers and reactors, and components such as capacitors (not shown) each having a relatively higher height in the Z direction are arranged on the downstream side (on the Y1-direction side) of the board 10, heat dissipation performance on the downstream side (Y1-direction side) can be improved. In other words, the power conversion apparatus 100 includes the frame 20 which holds the board 10, and includes the cooling fins 22 arranged on its back side (bottom side) opposite to a mount surface (cooling surfaces 21) of the board 10. The number of the cooling fins 22 that are relatively low is greater than the number of cooling fins 22 that are relatively high. It should be noted that a thickness, in the X direction, of the cooling fins 22 on the downstream side (Y1-direction side) that have a relatively lower height in the Z direction, can be smaller than a thickness, in the X direction, of the cooling fins 22 on the upstream side (Y2-direction side) that have relatively high.

The cooling fans 50 are configured to blow cooling air to cool the devices 11 mounted on the board 10. Specifically, two cooling fans 50 are arranged on the Y2-direction side of the frame 20. The cooling fans 50 are configured to draw air outside the power conversion apparatus 100 from the Y2-direction side and to blow cooling air to the cooling fins 22 of the frame 20. Cooling air from the cooling fans 50 flows through space on the Z2-direction side of the frame 20 and cools the cooling fins 22. A structure for fixing the cooling fan 50 will be described later in detail.

As shown in FIGS. 2 and 3, the top plate 30 is a metal plate arranged to cover the board 10, which is attached to the frame 20. The top plate 30 is arranged on the Z1-direction side (top side) of the frame 20 in the X-Y plane to cover the frame 20 and the board 10. The top plate 30 is formed from a metal plate by presswork.

In this embodiment, the top plate 30 has a top-plate folded part 31. The top-plate folded part 31 is formed by folding an end part of the top plate 30 on a side where the connectors 60 are arranged (Y1-direction side). The top-plate folded part 31 has a flat surface extending in an X-Z plane. Specifically, the top-plate folded part 31 is formed by folding an end part on the Y1-direction side of the top plate 30, which has a plate-like shape and formed from a metal plate, to extend in the Z2 direction. The top-plate folded part 31 prevents movement of the connectors 60. The prevention of movement of the connectors 60 by the top-plate folded part 31 (a structure for fixing the connector 60) will be described later in detail.

The bottom plate 40 is formed of a metal plate and arranged to face the top plate 30. The bottom plate 40 is arranged on the Z2-direction side (bottom side) of the frame 20 in the X-Y plane to cover the frame 20 with facing the top plate 30. Also, the bottom plate 40, which is arranged to cover the cooling fins 22 on the Z2-direction side of the frame 20, serves as a guide that directs cooling air from the cooling fans 50 toward the Y1-direction side.

In this embodiment, the bottom plate 40 has a bottom-plate folded part 41. The bottom-plate folded part 41 is formed by folding an end part of the bottom plate 40 on the side where the connectors 60 are arranged (Y1-direction side). Specifically, the bottom-plate folded part 41 is formed by folding an end part on the Y1-direction side of the bottom plate 40, which has a plate-like shape and formed from a metal plate, to extend in the Z1 direction. The bottom-plate folded part 41 prevents movement of the connectors 60. The prevention of movement of the connectors 60 by the bottom-plate folded part 41 (the structure for fixing the connector 60) will be described later in detail.

Also, as shown in FIGS. 3, 6 and 7, in this embodiment, the bottom plate 40 has ventilation holes 42. A plurality of (four) ventilation holes 42 are arranged on the Y1-direction side of the bottom plate 40. The ventilation holes 42 are formed to flow cooling air from the cooling fans 50 to the outside. The cooling air, which is drawn from the Y2-direction side by the cooling fans 50, flows on the Z2-direction side of the frame 20 toward the Y1-direction side, and is then discharged through the ventilation holes 42.

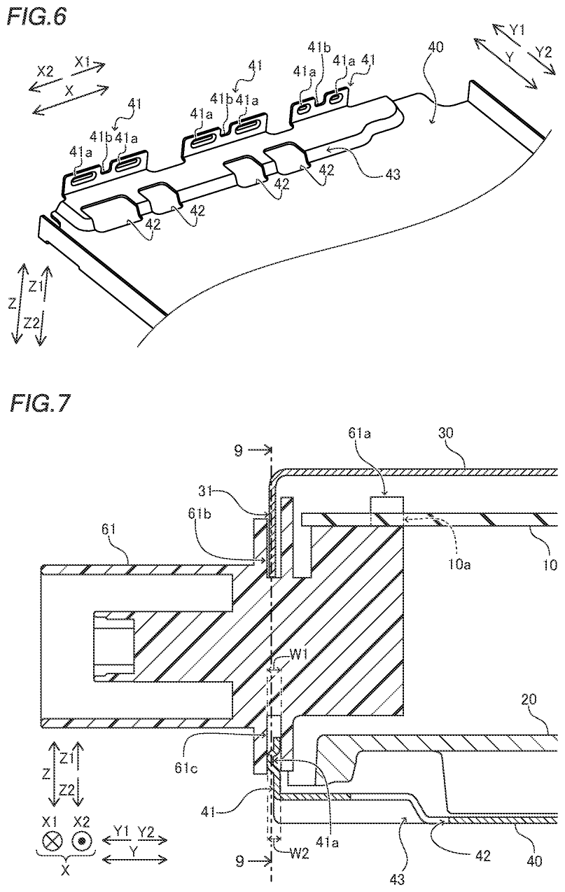

In this embodiment, the bottom-plate folded part 41 is formed on the end of the Y1-direction side of the bottom plate 40 by folding the bottom plate 40 twice into a stepped shape. The ventilation holes 42 are formed in a stepped section 43 of the bottom plate 40, which is formed by folding the bottom plate twice (see FIGS. 6 and 7). Specifically, the bottom plate 40 is first folded in a slant direction toward the Z1-direction side from the X-Y plane, and then folded again to extend in the X-Y plane whereby forming the stepped section 43 in the first folding. Subsequently, the bottom plate 40 is folded at a right angle in the Z1 direction to extend along a side surface part on the Y1-direction side of the frame 20 where the connectors 60 are placed whereby forming the bottom-plate folded part 41 in the second folding. The ventilation holes 42 are arranged in a stepped section 43 that is formed in the first folding to extend in the slant direction.

The connectors 60 include three connectors 61, 62 and 63 as shown in FIG. 2. In this embodiment, the board 10 is electrically connected to the outside of the power conversion apparatus 100 through the connectors 60 (connectors 61 to 62). The connector 61 is an example of a “first connector” in the claims. The connector 62 is an example of a “second connector” in the claims.

Specifically, the connector 61 is an input connector through which DC power is supplied from the battery 102 to the board 10. For example, the battery 102 is connected to the connector 61 by connecting wires such as an external harness. The DC power from the battery 102 is supplied to the board 10 through the connector 61. The connector 62 is an output connector configured to supply the external load 103 with AC power converted by power conversion function of the devices 11 mounted on the board 10. For example, the load 103 is connected to the connector 62 by connecting wires such as an external harness similar to the connector 61. AC power converted by switching function of the devices 11 is supplied from the board 10 through connector 62 to the load 103.

The connector 63 is a signal connector configured to provide the board 10 with control signals that control power conversion function of the devices 11. For example, an external control unit (not shown) can accept an instruction that activates output of AC power from the power conversion apparatus 100. In this case, a control signal that activates the power conversion function is provided to the board 10 through the connector 63 from signal wires connected to the connector 63. The devices 11 of the board 10 activate the power conversion function in response to the control signal provided through the connectors 63.

### Connector-Fixing Structure

In this embodiment, the connectors 60 (connectors 61 to 63) are fixed to the board 10 as shown in FIGS. 3 and 7. For example, the connector 61 is fixed to the board 10 by soldering connection terminals of the connector 61 to the board 10 to be electrically connected to the board 10 with legs 61a for fixing the connector 61 being inserted into openings 10a formed in the board 10. The connector 62 is similarly fixed to the board 10 with legs 62a included in the connector 62 being inserted into openings 10a formed in the board 10. The legs 61a and 62a have a snap-fit structure including a pawl, for example. The connector 63 is fixed to the board 10 by fasteners 63a, such as screws. Spaces 23 are provided on a side part of the frame 20 on the Y1-direction side to accommodate the connectors 61 to 63 so that the connectors 61 to 63 are not directly fixed to the frame 20.

As shown in FIGS. 7 to 9, in the power conversion apparatus 100, the connectors 60 (connectors 61 through 63) fixed to the board 10 are configured to prevent movement beyond a predetermined range by means of the top plate 30 and the bottom plate 40 whereby preventing a defect such as solder cracking or a fault such as warpage of the board 10 caused by a load (force) applied to the board 10 by the movement of the connectors 60. Specifically, in this embodiment, the top-plate folded part 31 of the top plate 30 and the bottom-plate folded part 41 of the bottom plate 40 contact the connectors 60 (connectors 61 to 63) whereby preventing movement of the connectors 60 (connectors 61 to 63). In the following description, a structure for fixing each connector 60 will be described for the connector 61 as an example of the connectors 60. Although the structure that prevents movement of the connector 61 is shown in FIGS. 7 to 9, the connectors 62 and 63 have structures similar to this structure for preventing their movements.

As shown in FIGS. 7, 8A and 8B, in this embodiment, the connector 61 has a groove 61b formed on the top side (Z1-direction side) to receive the top-plate folded part 31. The groove 61b is formed on the Z1-direction side of the connector 61 in a plane where the top-plate folded part 31 extends in the Z direction (X-Z plane). The connector 61 has a groove 61c formed on the bottom side (Z2-direction side) to receive the bottom-plate folded part 41. The groove 61c is formed on the Z2-direction side of the connector 61 opposite to the groove 61b on the Z1-direction side in a plane where the bottom-plate folded part 41 extends in the Z direction (X-Z plane). The groove 61b and groove 61c are examples of a “top-plate-side groove” and a “bottom-plate-side groove”, respectively, in the claims.

In this embodiment, the top-plate folded part 31 contacts an interior surface of the groove 61b with being inserted into the groove 61b whereby preventing movement of the connector 61 in a direction in which the bottom plate 40 and the top plate 30 face each other (Z direction). Specifically, the top-plate folded part 31 has an end part on the Z2-direction side contacting a bottom part of the groove 61b (surface on the Z2-direction side) whereby preventing movement of the connector 61 toward the Z1-direction side. The top-plate folded part 31 contacts the connector 61 on the Z1-direction side to prevent movement of the connector 61 beyond a predetermined range in which defects such as solder cracking or faults such as board warpage will not occur when a load is applied to the connector 61 toward the Z1-direction side. The top-plate folded part 31 does not include a part that increases a width in the Y direction such as convex sections 41a of the bottom-plate folded part 41 discussed later, and is formed to be a flat surface extending in the X-Z plane by folding the top plate 30. In addition, a gap is provided between the top-plate folded part 31 and the groove 61b so that no contact between the top plate 30 (top-plate folded part 31) and the connector 61 (groove 61b) occurs when no force such as vibration or load (force) that will move the connector 61 is applied to the connector 61.

In this embodiment, the bottom-plate folded part 41 contacts an interior surface of the groove 61c with being inserted into the groove 61c whereby preventing movement of the connector 61. Specifically, the bottom-plate folded part 41 has the convex sections 41a in a part that is inserted into the groove 61c of the connector 61. The convex section 41a bulges in a thickness direction (Y direction) in the part of the bottom-plate folded part 41 inserted into the connector 61. The bottom-plate folded part 41 can prevent movement of the connector 61 in the thickness direction (Y direction) in the part of the bottom-plate folded part 41 inserted into the connector 61 by means of the convex section 41a.

Specifically, two convex sections 41a are arranged in the X direction in the bottom plate folded part 41 (see FIG. 6). The convex section 41a is a bead (drawn section) formed by drawing in presswork. The convex sections 41a are formed by extruding the bottom-plate folded part 41, which extends in the X-Z plane, in the Y1 direction. The convex section 41a has a linear shape (rounded rectangular shape) extending in the X direction. The groove 61c of the connector 61 has a width W1 in the Y direction (see FIG. 7) slightly greater than a width W2 of the bottom-plate folded part 41 including the convex sections 41a in the Y direction (see FIG. 7). The convex sections 41a of the bottom-plate folded part 41 contacts the connector 61 to prevent movement of the connector 61 beyond a predetermined range in which defects such as solder cracking or faults such as board warpage will not occur when a load is applied to the connector 61 in the Y direction. As a result, in this embodiment, the power conversion apparatus 100 is configured to prevent movement of the connector 61 in the Y direction (thickness direction of the bottom-plate folded part 41) by using the convex sections 41a of the bottom-plate folded part 41, and movement of the connector 61 in the Z direction (direction in which the bottom plate 40 and the top plate 30 face each other) by using the top-plate folded part 31. The bottom plate 40 (bottom-plate folded part 41) is out of contact with the connector 61 (groove 61c) when no force such as vibration or load (force) that will move the connector 61 is applied to the connector 61 similar to the top plate 30 (top-plate folded part 31).

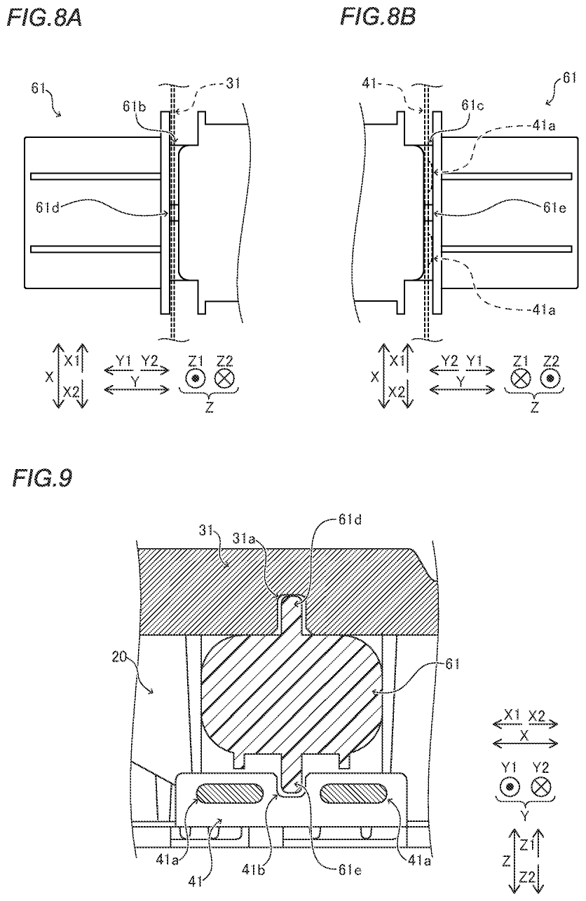

In addition, as shown in FIGS. 8A, 8B and 9, in this embodiment, the connector 61 has a connector protrusion 61d and a connector protrusion 61e that protrude toward the top plate 30 and the bottom plate 40, respectively. Specifically, the connector protrusion 61d protrudes from a central section in the X direction of a bottom of the groove 61b (surface on the Z2-direction side) in the Z1 direction toward the top plate 30. Also, the connector protrusion 61e protrudes from a central section in the X direction of a bottom of the groove 61c (surface on the Z1-direction side) in the Z2 direction toward the bottom plate 40.

In this embodiment, the bottom-plate folded part 41 has a concave cutout 41b. Movement of the connector 61 in the X direction, which is a direction orthogonal to the thickness direction of the bottom-plate folded part 41 and the direction in which the top plate 30 and the bottom plate 40 face each other (direction orthogonal to the Y and Z directions), is prevented by contact of the cutout 41b with the connector protrusion 61e. Also, the top-plate folded part 31 has a concave cutout 31a. Movement of the connector 61 in the X direction is prevented by contact of the cutout 31a with the connector protrusion 61d. In other words, the cutouts 31a and 41b are formed to contact the connector protrusions 61d and 61e, respectively, to prevent movement of the connector 61 beyond a predetermined range in which defects such as solder cracking or faults such as board warpage will not occur when a load is applied to the connector 61 in the X direction.

As shown in FIG. 3, the top-plate folded part 31 has three cutouts 31a corresponding to the connectors 61 to 63.

Also, as shown in FIGS. 6 and 9, three bottom-plate folded parts 41 are arranged corresponding to the connectors 61 to 63. The three bottom-plate folded parts 41 have their corresponding cutouts 41b to accommodate their corresponding one of the three connectors 61 to 63. Each bottom-plate folded parts 41 includes the convex sections 41a arranged on both sides of the cutout 41b in the X direction.

### Cooling-Fan-Fixing Structure

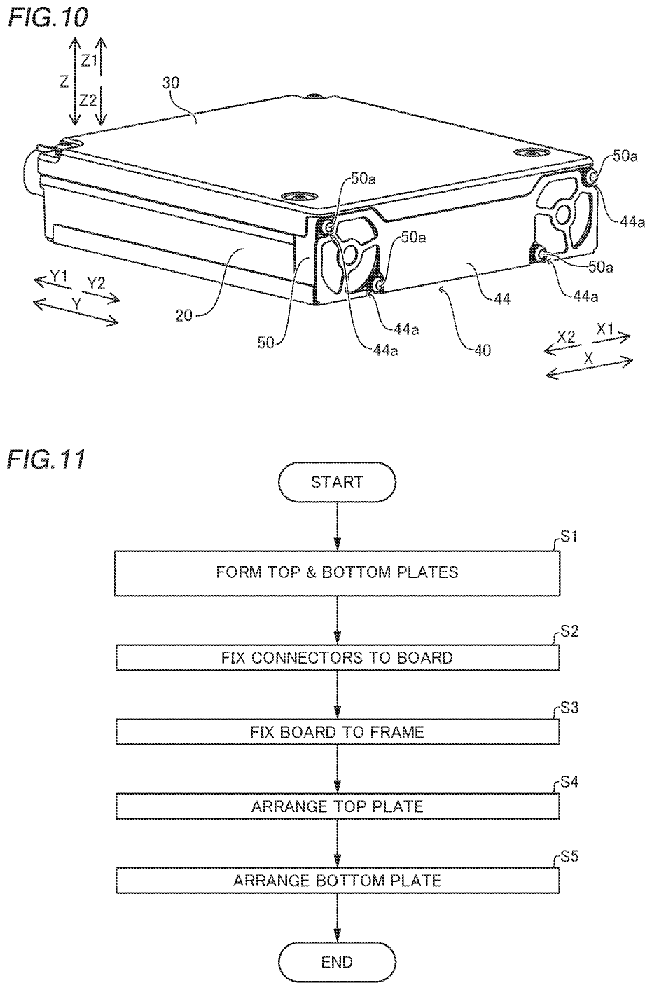

As shown in FIGS. 3 and 10, in this embodiment, the cooling fan 50 is securely fastened to the frame 20 by means of fasteners 50a such as screws. Specifically, the cooling fans 50 are arranged on a side part on the Y2-direction side opposite to the side part of the Y1-direction side where the connectors 60 of the frame 20 are arranged. The cooling fans 50 have a rectangular parallelepiped. At least two diagonal corners of the four corners of the cooling fan 50 are fixed to the frame 20 by the fasteners 50a. The bottom plate 40 has a cooling-fan-side folded part 44 formed by folding an end part of the bottom plate on the Y2-direction side to cover the cooling fans 50 on the Y2-direction side. The cooling-fan-side folded part 44 is not fixed to the cooling fans 50 but is cantilevered. The cooling-fan-side folded part 44 is cut to expose the fastener 50a of the cooling fans 50. Specifically, the cooling-fan-side folded part 44 has cutouts 44a for exposing the fasteners 50a to prevent contact with the fasteners 50a. This arrangement can reduce transmission of vibration of the cooling fans 50 running to the cooling-fan-side folded part 44 (bottom. plate 40) so that noises produced the cooling fan 50 running in the power conversion apparatus 100 can be reduced. In other words, the power conversion apparatus 100 includes the bottom plate 40, the frame 20 to which the board 10 is attached, the cooling fans 50 configured to blow cooling air to cool the devices 11 mounted on the board 10 and fixed to the frame 20 by means of fasteners 50a such as screws. The bottom plate 40 in the power conversion apparatus 100 includes the cooling-fan-side folded parts 44 having the cutouts 44a to expose the fasteners 50a for fastening the cooling fans 50.

### Advantages of Configuration of the Embodiment

In this embodiment, the following advantages are obtained.

In this embodiment, as described above, a bottom plate 40 formed of a metal plate includes a bottom-plate folded part 41 that is arranged on an end part of the bottom plate 40 on which the connectors 60 (connectors 61 to 63) are arranged, and is folded to contact the connectors 60 whereby preventing movement of the connectors 60. Accordingly, the connectors 60 can be fixed to the board 10 while preventing movement of the connectors 60 by means of the bottom-plate folded part 41, which is formed by folding the bottom plate 40 formed of a metal plate, without using fasteners such as screws. Because metal plate folding (presswork) can accurately convert material from one form into another form (accurate processing) while reducing processing time as compared with cutting, it is possible to prevent time increase of processing that forms a structure that prevents movement of the connectors 60 when the connectors 60 are fixed to the board 10. Consequently, it is possible to prevent apparatus configuration from becoming complicated while preventing increase of work time for production work. In addition, because movement of the connectors 60 can be prevented by the bottom-plate folded part 41, which is formed by folding the bottom plate 40, increase of the number of parts can be prevented while preventing movement of the connectors 60 as compared with a case in which the connectors 60 are fixed to a housing (frame 20) by means of fasteners such as screws.

In this embodiment, as described above, the connector 61 (connectors 60) has a groove 61c (bottom-plate-side groove) formed to receive the bottom-plate folded part 41, and the bottom-plate folded part 41 contacts an interior surface of the groove 61c with being inserted into the groove 61c of the connector 61 whereby preventing movement of the connector 61. According to this configuration, movement of the connector 61 can be effectively prevented by inserting the bottom-plate folded part 41 into the groove 61c of the connector 61. Consequently, defects such as solder cracking or faults such as board 10 warpage caused by the movement of the connector 61 can be effectively prevented.

In this embodiment, as described above, the bottom-plate folded part 41 has a convex section 41a that bulges in an area inserted into the groove 61c (bottom-plate-side groove) of the connector 61 in a thickness direction (Y direction) of the bottom-plate folded part 41 to prevent movement of the connector 61. Because the convex section 41a is provided, movement of the connector 61 can be more effectively prevented by contact of the convex section 41a of the bottom-plate folded part 41 with the connector 61. Because the movement of the connector 61 can be more effectively prevented, defects such as solder cracking or faults such as board 10 warpage caused by the movement of the connector 61 can be more effectively prevented.

In this embodiment, as described above, the top plate 30 has a top-plate folded part 31 that is folded on an end part of the top plate on which the connectors 60 (connectors 61 to 63) are arranged; and the connector 61 (connectors 60) has a groove 61b (top-plate-side groove) formed to receive the top-plate folded part 31, and the top-plate folded part 31 has a flat surface and contacts an interior surface of the groove 61b with being inserted into the groove 61b of the connector 61 whereby preventing movement of the connector 61. Accordingly, in addition to prevention of movement of the connector 61 by the convex section 41a of the bottom-plate folded part 41, the movement of the connector 61 can be more effectively prevented by the top-plate folded part 31. Because the movement of the connector 61 can be further more effectively prevented if a load is applied to the connector 61, defects such as solder cracking or faults such as board 10 warpage caused by the movement of the connector 61 can be further more effectively prevented.

In this embodiment, as discussed above, a frame 20 to which the board 10 is attached is further provided, wherein the top plate 30 is arranged to cover the board 10 attached to the frame 20; and the bottom plate 40 is arranged to cover the frame 20 with facing the top plate 30. According to this configuration, even in a case in which a frame 20 that holds the board 10 is produced by removing its material by cutting, etc., movement of the connectors 60 (connectors 61 to 63) can be prevented not by the frame 20 but by the bottom plate 40 by folding the bottom plate 40 formed of a metal plate. Consequently, even in a case in which a frame 20 that holds the board 10 is produced by removing its material by cutting, etc., movement of the connectors 60 can be prevented by the bottom plate 40 arranged to cover the frame 20 while preventing increase of work time for production work.

In this embodiment, as discussed above, cooling fans 50 configured to blow cooling air to cool the devices 11 mounted on the board 10 is provided, wherein the bottom plate 40 has ventilation holes 42 formed to flow the cooling air from the cooling fans 50 to the outside. According to this configuration, in a case in which the bottom-plate folded part 41 configured to prevent movement of the connectors 60 (connectors 61 to 63) is provided by folding the bottom plate 40, by forming the ventilation holes 42, the bottom-plate folded part 41 of the bottom plate 40 can be prevented from blocking a flow path of cooling air. Consequently, in a case in which bottom plate 40 is folded to prevent movement of the connectors 60, reduction of cooling efficiency of the cooling fans 50 can be prevented.

In this embodiment, as discussed above, the bottom-plate folded part 41 is formed by folding the bottom plate 40 in a stepped shape on the end part of the bottom plate 40 on which the connectors 60 (connectors 61 to 63) are arranged; and the ventilation holes 42 are formed in a stepped section 43 of the bottom plate 40 formed by folding the bottom plate 40 in a stepped shape. According to this configuration in which the ventilation holes 42 are formed in a stepped section 43 of the bottom plate 40 formed by folding the bottom plate 40 in a stepped shape, the ventilation hole 42 can have a larger opening area. As a result, it is possible to further prevent the bottom-plate folded part 41 of the bottom plate 40 from blocking a flow path of cooling air. Consequently, it is possible to further prevent reduction of cooling efficiency of the cooling fans 50.

In this embodiment, as discussed above, the connector 61 (connectors 60) includes a connector protrusion 61e protruding toward the bottom plate 40; and the bottom-plate folded part 41 has a concave cutout 41b that is formed to contact the connector protrusion 61e whereby preventing movement of the connector 61 in a direction (X direction) orthogonal to the thickness direction of the bottom-plate folded part 41 and a direction in which the top plate 30 and the bottom plate 40 face each other. According to this configuration, the connector protrusion 61e and the cutout 41b of the bottom-plate folded part 41 can prevent movement of the connector 61 in a direction (X direction) orthogonal to the thickness direction of the bottom-plate folded part 41 and a direction in which the top plate 30 and the bottom plate 40 face each other. Consequently, because the movement of the connector 61 can be further prevented by contact of the cutout 41b and the connector protrusion 61e, defects such as solder cracking or faults such as board 10 warpage caused by the movement of the connector 61 can be further prevented.

In this embodiment, as discussed above, a connector 61 (first connector) configured to supply the board 10 with DC power from an external battery 102 installed on a vehicle 101, and a connector 62 (second connector) configured to supply an external load 103 with AC power converted by power conversion function of the devices 11 mounted on the board 10, are provided as the connectors 60; and the bottom-plate folded part 41 contacts the first and second connectors 61 and 62 whereby preventing movement of the first and second connectors 61 and 62. According to this configuration, even when vibration caused by motion of vehicle 101 is applied to the power conversion apparatus 100, the bottom-plate folded part 41 can effectively prevent movement of the connectors 61 and 62.

### Power-Conversion-Apparatus Production Method

A power-conversion-apparatus production method according to this embodiment is now described with reference to FIGS. 3 and 11.

In step S1, top and bottom plates 30 and 40 are first formed by presswork.

Specifically, as shown in FIG. 3, an end part of the top plate 30, which is formed of a metal plate and arranged on a top surface side (Z1-direction side) of a board 10, on a side where the connectors 60 are arranged (on the Y1-direction side) is folded by presswork so that a top-plate folded part 31 is formed. In addition, an end part of the bottom plate 40, which is formed of a metal plate and arranged on a bottom surface side (Z2-direction side) of the board 10, on a side where in which the connectors 60 are arranged (on the Y1-direction side) is folded by presswork so that a bottom-plate folded part 41 is formed.

Subsequently, in step S2, the connectors 60 (connectors 61 to 63), which are configured to electrically connect an external side to the board 10 including devices 11 for power conversion mounted on the board 10, is fixed to the board 10. Also, a circuit configuration including the devices 11 is mounted to the board 10.

Subsequently, in step S3, the board 10 is attached to a frame 20 formed by removing its material by cutting.

Subsequently, in step S4, the top plate 30 is arranged to cover a top side (Z1-direction side) of the board 10 attached to the frame 20.

Subsequently, in step S5, the bottom plate 40 is arranged to cover a bottom side (Z2-direction side) of the frame 20 with facing the top plate 30. Specifically, the bottom plate 40, which is formed of a metal plate, is arranged to face the top plate 30 so that the bottom-plate folded part 41 of the bottom plate 40, which has been folded, contacts the connectors 60 (connectors 61 to 63) whereby preventing movement of the connectors 60.

It should be noted that either arranging the top plate 30 in the step S4 or arranging the bottom plate 40 in the step S5 can be previously executed.

### Advantages of Power-Conversion-Apparatus Production Method of Embodiment

In this embodiment, the following advantages are obtained.

As discussed above, a production method of a power conversion apparatus 100 according to this embodiment includes a step of folding by presswork an end part of a bottom plate 40, which is formed of a metal plate and arranged on a bottom surface side of a board 10, on a side where connectors 60 are arranged (step S1); and a step of arranging the bottom plate 40, which is formed of a metal plate, to face a top plate 30 so that the bottom-plate folded part 41 of the bottom plate 40, which has been folded, contacts the connectors 60 whereby preventing movement of the connectors 60 (step S5). Accordingly, the connectors 60 can be fixed to the board 10 while preventing movement of the connectors 60 by means of the bottom-plate folded part 41, which is formed by folding the bottom plate 40 formed of a metal plate, without using fasteners such as screws. Because metal plate folding (presswork) can accurately convert material from one form into another form (accurate processing) while reducing processing time as compared with cutting, it is possible to prevent time increase of processing that forms a structure that prevents movement of the connectors 60 when the connectors 60 are fixed to the board 10. As a result, it is possible to reduce the complexity of the equipment configuration and to provide a manufacturing method for the power conversion apparatus 100 that can prevent the increase in the work time of the manufacturing work. In addition, because movement of the connectors 60 can be prevented by the bottom-plate folded part 41, which is formed by folding the bottom plate 40, increase of the number of parts can be prevented while preventing movement of the connectors 60 as compared with a case in which the connectors 60 are fixed to a housing (frame 20) by means of fasteners such as screws.

### Modification Example

Note that the embodiment disclosed this time must be considered as illustrative in all points and not restrictive. The scope of the present invention is not shown by the above description of the embodiments but by the scope of claims for patent, and all modifications (modified examples) within the meaning and scope equivalent to the scope of claims for patent are further included.

For example, while the example in which the connector 61 (the connectors 60) has a groove 61c into which the bottom-plate folded part 41 is inserted has been shown in the aforementioned embodiment, the present invention is not limited to this. For example, the connector 61 (the connectors 60) may not have the groove 61c, but the bottom-plate folded part 41 may contact a bottom (Z2-direction side) of the connectors 60. Alternatively, the groove 61c may be formed in the bottom-plate folded part 41 side so that a convex section 41a provided on the connector 60 side may be inserted into the groove 61c in the bottom-plate folded part 41 side.

Also, while the example in which the bottom-plate folded part 41 includes a convex section 41a has been shown in the aforementioned embodiment, the present invention is not limited to this. For example, the bottom-plate folded part 41 may not have the convex section 41a but may have a flat surface. Alternatively, the entire width (thickness) of the bottom-plate folded part 41 may be larger.

Also, while the example in which the top plate 30 includes a top-plate folded part 31 having a flat surface, and the bottom plate 40 includes the bottom-plate folded part 41 having a convex section 41a has been shown in the aforementioned embodiment, the present invention is not limited to this. For example, the top plate 30 may include a top-plate folded part 31 having a convex section, and the bottom plate 40 may include a bottom-plate folded part 41 having a flat surface (without the convex section 41a).

Also, while the example in which the frame 20 to which the board 10 is attached is interposed between the top plate 30 and the bottom plate 40 has been shown in the aforementioned embodiment, the present invention is not limited to this. For example, in addition to the top plate 30 and the bottom plate 40, side plates that form side surface parts may be provided.

Also, while the example in which a cooling fan 50 configured to blow cooling air is provided and ventilation holes 42 are formed in the bottom plate 40 to flow cooling air from the cooling fan 50 has been shown in the aforementioned embodiment, the present invention is not limited to this. For example, the cooling fan 50 may not be provided. Also, the ventilation holes may be formed not in the bottom plate 40 but in the frame 20, which forms the side surface parts.

Also, while the example in which the bottom-plate folded part 41 is formed by folding the bottom plate 40 in a stepped shape has been shown in the aforementioned embodiment, the present invention is not limited to this. For example, the bottom-plate folded part 41 may be formed by folding the bottom plate 40 once.

Also, while the example in which the connector 61 has a connector protrusion 61d and a connector protrusion 61e that protrude toward the top plate 30 and the bottom plate 40, respectively, and the top-plate folded part 31 and the bottom-plate folded part 41 have the cutout 31a and 41b has been shown in the aforementioned embodiment, the present invention is not limited to this. For example, the cutouts 31a and 41b may not be formed in the top plate 30 and the bottom plate 40. Alternatively, either the top plate 30 or the bottom plate 40 may have the cutout 31a (or the cutout 41b). Also, the top-plate folded part 31 or the bottom-plate folded part 41 may have two cutouts 31a or 41b.

Also, while the example in which the power conversion apparatus 100 is an inverter configured to convert DC power supplied from the battery 102 installed on the vehicle 101 has been shown in the aforementioned embodiment, the present invention is not limited to this. For example, the power conversion apparatus 100 may be an inverter that converts AC power from an AC power supply and provides the converted power.

Also, while the example in which the convex section 41a is a bead formed in a linear shape by drawing in presswork of the bottom-plate folded part 41 has been shown in the aforementioned embodiment, the present invention is not limited to this. For example, a convex section 41a may be formed by increasing a thickness of a part of the bottom-plate folded part 41. The convex section 41a may be formed in a circular shape instead of such a linear shape.

What is claimed is:

1. A power conversion apparatus comprising:
a board including a device for power conversion mounted on the board;
a connector fixed to the board and configured to electrically connect the board to an external side;
a top plate formed of a metal plate and arranged to cover the board; and
a bottom plate formed of a metal plate and arranged to face the top plate, wherein
the bottom plate includes a bottom-plate folded part that is arranged on an end part of the bottom plate on which the connector is arranged, and is folded to contact the connector whereby preventing movement of the connector.

2. The power conversion apparatus according to claim 1, wherein
the connector has a bottom-plate-side groove into which the bottom-plate folded part is inserted; and
the bottom-plate folded part contacts an interior surface of the bottom-plate-side groove with being inserted into the bottom-plate-side groove of the connector whereby preventing movement of the connector.

3. The power conversion apparatus according to claim 2, wherein the bottom-plate folded part has a convex section that bulges in an area inserted into the bottom-plate-side groove of the connector in a thickness direction of the bottom-plate folded part to prevent movement of the connector.

4. The power conversion apparatus according to claim 3, wherein
the top plate has a top-plate folded part that is folded on an end part of the top plate on which the connector is arranged;
the connector has a top-plate-side groove into which the top-plate folded part is inserted; and
the top-plate folded part has a flat surface, and contacts an interior surface of the top-plate-side groove with being inserted into the top-plate-side groove whereby preventing movement of the connector.

5. The power conversion apparatus according to claim 1, further comprising
a frame to which the board is attached, wherein
the top plate is arranged to cover the board attached to the frame; and
the bottom plate is arranged to cover the frame with facing the top plate.

6. The power conversion apparatus according to claim 1, further comprising
a cooling fan configured to blow cooling air to cool the device mounted on the board, wherein
the bottom plate has a ventilation hole formed to flow the cooling air from the cooling fan to an outside.

7. The power conversion apparatus according to claim 6, wherein
the bottom-plate folded part is formed by folding the bottom plate in a stepped shape on the end part of the bottom plate on which the connector is arranged; and
the ventilation hole is formed in a stepped section of the bottom plate formed by folding the bottom plate in a stepped shape.

8. The power conversion apparatus according to claim 1, wherein
the connector includes a connector protrusion protruding toward the bottom plate; and
the bottom-plate folded part has a concave cutout that is formed to contact the connector protrusion whereby preventing movement of the connector in a direction orthogonal to a thickness direction of the bottom-plate folded part and a direction in which the top plate and the bottom plate face each other.

9. The power conversion apparatus according to claim 1, wherein
the connector includes a first connector configured to supply the board with DC power from an external battery installed on a vehicle, and a second connector configured to supply an external load with AC power converted by power conversion function of the device mounted on the board; and
the bottom-plate folded part contacts each of the first and second connectors whereby preventing movement of the first and second connectors.

10. A connector-fixing structure comprising:
a board including an electronic part mounted on the board;
a connector fixed to the board and configured to electrically connect the board to an external side;
a top plate formed of a metal plate and arranged to cover the board; and
a bottom plate formed of a metal plate and arranged to face the top plate, wherein
the bottom plate includes a bottom-plate folded part that is arranged on an end part of the bottom plate on which the connector is arranged, and is folded to contact the connector whereby preventing movement of the connector.

11. A power-conversion-apparatus production method comprising:
a step of fixing a connector configured to electrically connect an external side to a board including a device for power conversion mounted on the board;
a step of arranging a top plate formed of a metal plate to cover a top surface side of the board;
a step of folding by presswork an end part of a bottom plate, which is formed of a metal plate and arranged on a bottom surface side of the board, on a side where the connector is arranged; and
a step of arranging the bottom plate to face the top plate so that a bottom-plate folded part of the bottom plate, which has been folded, contacts the connector whereby preventing movement of the connector.
